(19) United States
(12) Patent Application Publication
(10) Pub. No.: US 2010/0086087 A1
(43) Pub. Date: Apr. 8, 2010

(54) Transmission Enhancements for Physical Layer Transmission

(75) Inventors: Harri Pekonen, Raisio (FI); Jussi Vesma, Turku (FI); Tero Jokela, Turku (FI)

Correspondence Address: BANNER & WITCOFF, LTD., 1100 13th STREET, N.W., SUITE 1200, WASHINGTON, DC, 20005-4051, US

(73) Assignee: Nokia Corporation, Espoo (FI)

(21) Appl. No.: 12/244,404

(22) Filed: Oct. 2, 2008

(51) Int. Cl. H03D 1/04

(52) U.S. Cl. 375/346

(57) ABSTRACT

Aspects of the invention provide apparatuses, computer media, and methods for supporting the broadcast of signaling data over a network. Error detection and protection as well as modulation mechanisms enhance the flexibility and robustness of signaling data for digital video broadcasting. A first error detection code for a first portion of signaling data and a second error detection code for a second portion of the signaling data are determined. The signaling data is combined with data and transmitted as a digital stream through a digital terrestrial television broadcasting system. A portion of the signaling data may include a configurable part and a dynamic part or may include different dynamic parts of the signaling data. Different portions of the signaling data may be separately modulated and encoded. A portion of the signaling data may be divided over a plurality of code words and evenly distributed over a transmission period.

### BACKGROUND

Digital Video Broadcasting (DVB) systems distribute data using a variety of approaches, including by satellite (DVB-S, DVB-S2 and DVB-SH), DVB-SMATV for distribution via SMATV), cable (DVB-C), terrestrial television (DVB-T, DVB-T2), and digital terrestrial television for handhelds (DVB-H, DVB-SH). The associated standards define the physical layer and data link layer of the distribution system. Devices interact typically with the physical layer through a synchronous parallel interface (SPI), synchronous serial interface (SSI), or asynchronous serial interface (ASI). Data is typically transmitted in MPEG-2 transport streams with some additional constraints (DVB-MPEG).

The distribution systems for the different DVB standards differ mainly in the modulation schemes used and error correcting codes used, due to the different technical constraints.

For example, DVB-S (SHF) uses QPSK, 8PSK or 16-QAM. DVB-S2 uses QPSK, 8PSK, 16APSK or 32APSK, based as a broadcaster's option. QPSK and 8PSK are the only versions regularly used. DVB-C (VHF/UHF) uses QAM: 16-QAM, 32-QAM, 64-QAM, 128-QAM or 256-QAM. DVB-T (VHF/UHF) uses 16-QAM or 64-QAM (or QPSK) in combination with COFDM and can support hierarchical modulation.

The DVB-T2 standard (e.g., “Frame structure channel coding and modulation for a second generation digital terrestrial television broadcasting system (DVB-T2),” DVB Document A122, June 2008) is an update for DVB-T to provide enhanced quality and capacity. It is expected that the DVB-T2 standard will provide more-robust TV reception and increase the possible bit-rate by over 30% for single transmitters (as in the UK) and is expected to increase the maximum bit rate by over 50% in large single-frequency networks (as in Germany, Sweden). However, there are real market needs to further enhance capacity in order to support additional services for mobile devices with the available broadcast spectrum.

### SUMMARY

An aspect provides apparatuses, computer-readable media, and methods for supporting the broadcast of signaling data over a network. Error detection and protection as well as modulation mechanisms enhance the flexibility and robustness of signaling data for digital broadcasting of video, audio or other media. By separately encoding different portions of the signaling data, a data frame may be utilized even though a portion of the signaling data contains an error while another portion of the signaling data does not.

According to another aspect of the invention, a first error detection code for a first portion of signaling data and a second error detection code for a second portion of the signaling data are determined. The signaling data is combined with data symbols and transmitted as a digital stream through a digital terrestrial television broadcasting system. A portion of the signaling data may include a configurable part and a dynamic part or may include different dynamic parts of the signaling data.

According to another aspect of the invention, different portions of the signaling data may be separately modulated and encoded.

According to another aspect of the invention, a portion of the signaling data is divided over a plurality of code words and evenly distributed over a transmission period.

### BRIEF DESCRIPTION OF THE DRAWINGS

A more complete understanding of the present invention and the advantages thereof may be acquired by referring to the following description in consideration of the accompanying drawings, in which like reference numbers indicate like features and wherein:

FIG. 1 shows physical layer (L1) signaling transmission in T2 frames in accordance with prior art.

FIG. 2 shows L1 signaling with dynamic signaling parts in accordance with prior art.

FIG. 3 shows L1 signaling encoding in accordance with prior art.

FIG. 4 shows an error detection mechanism for different parts of L1 post-signaling in accordance with an embodiment of the invention.

FIG. 5 shows an error correction and detection mechanism for different parts of L1 post-signaling in accordance with an embodiment of the invention.

FIG. 6 shows an error correction and detection mechanism when a L1 post-dynamic part does not fit into one code word in accordance with an embodiment of the invention.

FIG. 7 shows an apparatus for generating a digital stream in accordance with an embodiment of the invention.

FIG. 8 shows an apparatus for processing a digital stream in accordance with an embodiment of the invention.

FIG. 9 shows a flow diagram for generating a data stream in accordance with an embodiment of the invention.

FIG. 10 shows a flow diagram for processing a data stream in accordance with an embodiment of the invention.

### DETAILED DESCRIPTION

In the following description of the various embodiments, reference is made to the accompanying drawings which form a part hereof, and in which is shown by way of illustration various embodiments in which the invention may be practiced. It is to be understood that other embodiments may be utilized and structural and functional modifications may be made without departing from the scope of the present invention.

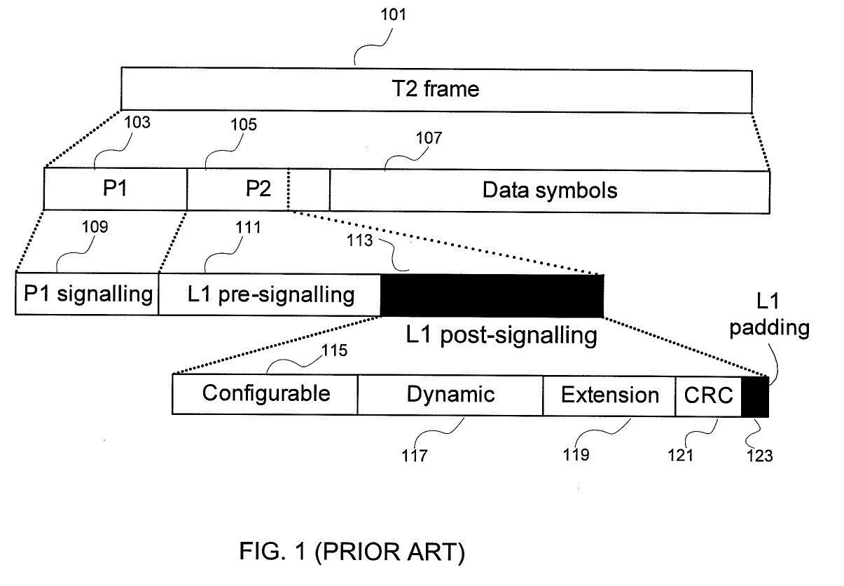

FIG. 1 shows layer 1 (L1) signaling transmission in T2 frame 101 corresponding to the physical layer as specified in “Frame structure channel coding and modulation for a second generation digital terrestrial television broadcasting system (DVB-T2),” DVB Document A122, June 2008 in accordance with prior art. The physical layer is the first (i.e., the “lowest”) level in the seven-layer OSI model of computer networking. The physical layer translates communications requests from the data link layer into hardware-specific operations to affect transmission or reception of electronic signals. The bit stream may be grouped into code words or symbols and converted to a physical signal that is transmitted over a hardware transmission medium.

Each frame 101 contains one P1 symbol 103, P2 symbols 105, and data symbols 107. (Each frame typically includes only one P1 symbol, although embodiments may include a plurality of P1 symbols.) P1 symbol 103 is fixed pilot symbol that carries P1 signaling information 109 and is located in the beginning of frame 101 within each RF-channel. P1 symbol 103 is typically used for a fast initial signal scan. P2 symbols 105 are pilot symbol located right after P1 symbol 103 with the same FFT-size and guard interval as the data symbols. P2 symbols carry L1 pre-signaling information 111 and L1 post-signaling information 113. The number of P2 symbols depends on the FFT-size. P2 symbols 105 are typically used for fine frequency and timing synchronization as well as for initial channel estimates. Data symbols 107 are OFDM symbols in frame 101 that are not P1 or P2 symbols. Data symbols 107 typically convey data content that are associated with different physical layer pipes (PLPs). T2 frames are further grouped into super frames, consisting of selected number of frames.

In DVB-T2, data is transmitted through PLPs (Physical Layer Pipes) where different PLPs may have different coding and modulation parameters. Signaling at the physical layer indicates how to decode the different PLPs. This L1 signaling is transmitted in a preamble, consisting of P2 OFDM symbols.

As discussed above, L1 signaling is divided into pre-signaling (L1-pre) 111 and post-signaling (L1-post) 113, where L1-pre 111 acts as a key for receiving L1 post-signaling 113 including the PLP mappings.

L1-post 113 is further divided into configurable part 115 and dynamic part 117, where configurable parameters comprise static signaling data that may change only at super frame border. Configurable parameters change only when the system configuration is changed (e.g., when PLPs are added or removed). Dynamic parameters refer to the mapping of each PLP to T2 frame 101 and may change from frame to frame. Configurable and dynamic parts 115 and 117 of L1 post-signaling 113 are transmitted in the same code words.

L1 post signaling 113 may also include optional extension field 119 that allows for expansion of L1 post-signaling. CRC (cyclic redundancy check) 121 provides error detection of any errors that may occur in L1 post-signaling 113. A 32-bit error detection code is applied to the entire L1 post-signaling 113 including configurable part 115, dynamic part 117, and extension part 119. L1 padding 123 is a variable-length field that is inserted following the L1-post CRC field 121 to ensure that multiple LDPC blocks of the L1 post-signaling have the same information size when the L1 post-signaling is segmented into multiple blocks and when these blocks are separately encoded. The values of the L1 padding bits, if any, are set to “0”.

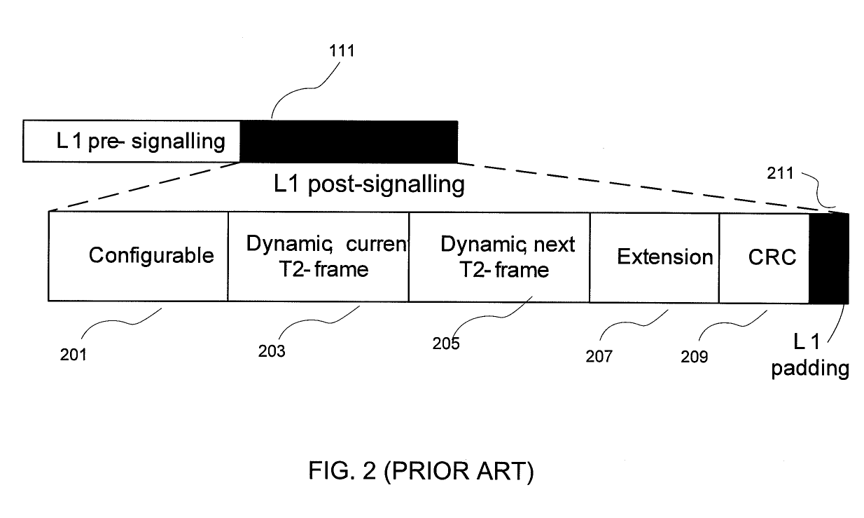

FIG. 2 shows L1 signaling with dynamic signaling parts in accordance with prior art. L1 post signaling 111 includes configurable part 201, dynamic parts 203 and 205, extension field 207, CRC 209 and L1 padding 211. Dynamic part 203 provides dynamic information about the current frame. Dynamic part 205 may be optionally included to provide dynamic information about the next frame.

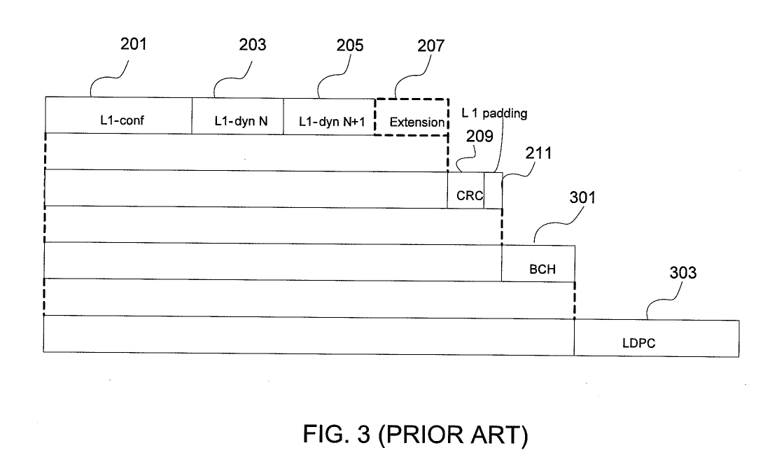

FIG. 3 shows L1 signaling encoding in accordance with prior art. L1 signaling (including configurable part 201, dynamic parts 203 and 205, extension field 207, CRC 209, and padding 211) are further encoded with BCH field 301 and LDPC field 303, which provide further error protection of L 1 post-signaling 113.

L1-dynamic part 203 and 205 can signal PLP to frame mappings either for only the current frame or optionally for both the current frame and the next frame. In the former case only the L1-dynamic part 203 is present, whereas in the latter case also the L1-dynamic part 205 is included. In both cases, the entire L1 post-signaling is handled as one block as shown in FIG. 3. CRC 209 is calculated over configurable part 201, dynamic parts 203, optional dynamic part 205, and optional extension part 207 of L1 post-signaling 113. Bose-Chaudhuri-Hocquenghem (BCH) and Low Density Parity Check (LDPC) codes are further used for error correction and detection. BCH field 301 and LDPC 303 are coded over configurable part 201, dynamic parts 203 and 205, extension part 207, CRC 209, and possible L1 padding 211. Consequently, an error anywhere in L1 post-signaling 113 may result in discarding all parts of the L1 post-signaling at the receiver as it is not known whether the entire received L1 post-signaling information is corrupted or whether some portions of the received L1 post-signaling information are not corrupted.

For example, if the receiver is only interested in dynamic information corresponding to a set of PLPs for a desired service, the receiver may use L1 dynamic information received as part of a L1 post-signaling block containing some errors if the receiver could ascertain that the error is in other parts of L1 post-signaling. Similarly, in case the dynamic part includes signaling for both current and next frame PLP to frame mapping, the receiver could continue receiving data from current frame if the error were known to be in the part of signaling associated with the next frame.

The approach shown in FIG. 3, where the L1 post-signaling is encoded as one block, generally does not support different degrees of robustness for different parts of the L1 post-signaling.

The scheme shown in FIG. 3 may be further evolved based on the second generation terrestrial digital video broadcasting standard DVB-T2. Embodiments of the invention support changes to the DVB-T2 standard (e.g., “Frame structure channel coding and modulation for a second generation digital terrestrial television broadcasting system (DVB-T2),” DVB Document A122, June 2008) to enhance the needs of a mobile system.

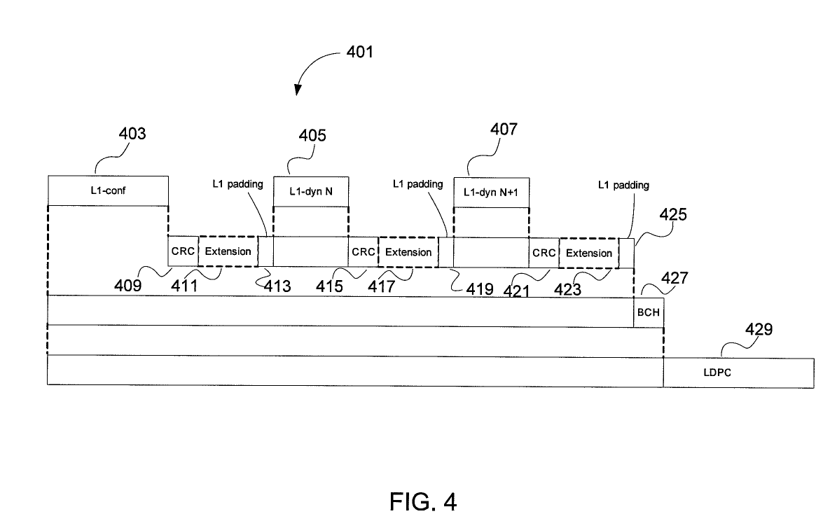

FIG. 4 shows an error detection mechanism for different parts of L1 post-signaling in accordance with an embodiment of the invention. With an embodiment of the invention, different L1 post-signaling parts 403, 405, and 407 are separated in order to add a mechanism for error detection for each part. Consequently, the receiver is able to utilize L1 post-signaling from partially erroneous BCH/LDPC code words when errors are not located in the signaling part that the receiver is processing.

FIG. 4 shows an embodiment of the invention, in which separate CRC (cyclic redundancy check) fields are associated with each part of L1 post signaling 401. CRC fields 409, 415, and 421 are associated with configurable (L1-conf) part 403, dynamic (L1-dyn) part 405, and dynamic part 407, respectively. With another embodiment of the invention (not shown), L1-conf may have its own CRC, while L1-dyn N and L1-dyn N+1 share another common CRC checksum. (N refers to the current frame while N+1 refers to the next frame.)

Cyclic redundancy check codes (CRC-codes) allow the detection of transmission errors at the receiver side. For this purpose, CRC words are included in the transmitted data. A cyclic redundancy check may be referred as a redundancy check or checksum. The CRC calculation may be performed by means of a shift register containing register stages in accordance with the corresponding CRC polynomial. An error detection code includes a checksum, CRC, and other error detection/correction mechanisms.

As shown in FIG. 4, different possible locations for extension fields 411, 417, and 423 and L1 padding fields 413, 419, and 425 are shown. An extension field may be in one or several locations shown in FIG. 4 and may or may not include its own CRC.

Alternatively, a CRC covering an extension and one or more parts of the L1 post signaling may be supported. For example, if a single extension is used and is placed after the L1-conf, a common CRC may be used to cover both L1-conf and the extension field following it.

With an embodiment of the invention, BCH field 427 and LDPC field provide further error protection for fields 403-425.

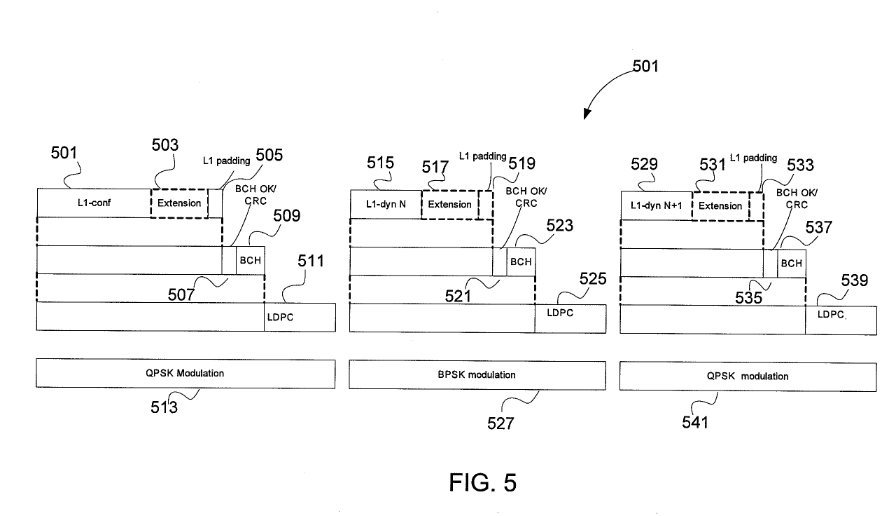

FIG. 5 shows an error correction and detection mechanism for different parts of L1 post-signaling 501 in accordance with an embodiment of the invention. Separate encoding and modulation are supported for separate parts of the L1 post-signaling 501. Consequently, a receiver is enabled to receive only desired L1 post-signaling parts and to error correct and detect errors if the desired signaling parts are received correctly or not. For example, separate encoding and modulation may be used for L1-conf 501, L1-dyn 515, and L1-dyn 529. Weaker modulation may be used for L1-conf 501 than is used for L1-dyn 515, since L1-conf represents static part of the signaling data, which remains unchanged throughout a T2 super frame and the same L1-conf information is provided in all frames of a super frame. Consequently, as exemplified in FIG. 5, QSPK modulation 513, BPSK modulation 527, and QPSK modulation 541 are used during L1-conf part 501, L1-dyn part 515, and L1-dyn part 529, respectively.

In the embodiment shown in FIG. 5, BCH field 509 spans L1-conf 501, extension field 503, L1 padding 505, and CRC 507. Similarly, BCH field 523 spans fields 515-521 and BCH field 537 spans fields 529-535. Also, LDPC fields 511, 525, and 539 span fields 501-509, fields 515-523, and fields 529-537, respectively. LDPC fields 511, 525, and 539 may be associated with the same code rate or with different code rates.

Because separate BCH/LDPC fields are associated with each signaling part, BCH fields 509, 523, and 537 may be used as an error correction mechanism as well as an error detection mechanism. Consequently, embodiments of the invention may include BCH OK fields 507, 521, and 535 that indicate whether the corresponding signaling part contains errors or not. In embodiments employing the BCH OK field, the CRC field may or may not be included. In one embodiment BCH OK fields 507, 521, and 535 may be part of the data transmitted as L1 post-signaling. In another embodiment, BCH OK fields 507, 521, and 535 may be added in the receiving end to be used in the subsequent processing. In embodiments that transmit the BCH OK field, the received value of this field can be ignored and replaced with a value indicating weather the received frame was corrupted or not. The sender can set the BCH OK field to any value, for example to a value indicating valid data.

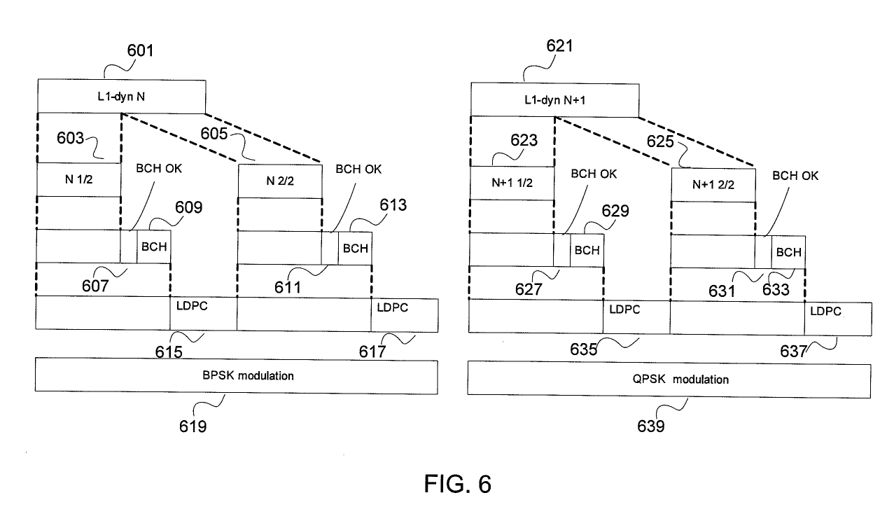

FIG. 6 shows an example of an error correction and detection mechanism when an L1 post-dynamic part does not fit into one code word in accordance with an embodiment of the invention. L1 post-signaling parts are divided into several BCH/ LDPC code words when signaling does not fit into one code word. For example, L1-dyn part 601 is divided into a first code word spanning 603, 607, 609, and 615 and a second code word spanning 605, 611, 613, and 617. Similarly, L1-dyn part 621 is divided into a first code word spanning 623, 627, 629, and 635 and a second code word spanning 625, 631, 633, and 637. The code words may be spread evenly over the whole transmission period.

While BCH and LDPC coding may be used to provide error protection, embodiments of the invention may utilize other codes such as Turbo codes.

Dynamic parts 601 and 621 may be differently modulated, for example corresponding to BPSK modulation 619 and QPSK modulation 639, respectively, as illustrated in the example of FIG. 6.

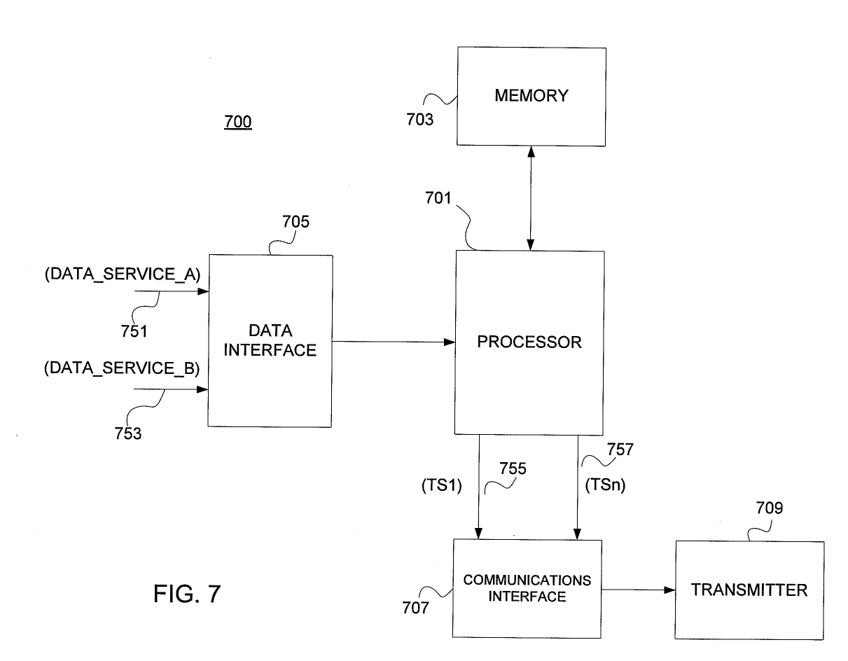

FIG. 7 shows apparatus 700 for generating a digital stream in accordance with certain embodiments of the invention. Processor 701 obtains content 751, 753 for services A and B through data interface 705 and generates a data stream, which may comprise transport streams (TS) 755 and 757. (A service is typically conveyed in one transport stream, although may be conveyed in a plurality of transport streams.) The data stream is transmitted by transmitter 709 over a communications channel (e.g., a digital terrestrial television broadcasting system) through communications interface 707.

Processor 701 may execute computer executable instructions from a computer-readable medium, e.g., memory 703. Computer storage media may include volatile and nonvolatile, removable and non-removable media implemented in any method or technology for storage of information such as computer readable instructions, data structures, program modules or other data. Computer storage media include, but is not limited to, random access memory (RAM), read only memory (ROM), electronically erasable programmable read only memory (EEPROM), flash memory or other memory technology, CD-ROM, digital versatile disks (DVD) or other optical disk storage, magnetic cassettes, magnetic tape, magnetic disk storage or other magnetic storage devices, or any other medium that can be used to store the desired information and that can be accessed by processor 701.

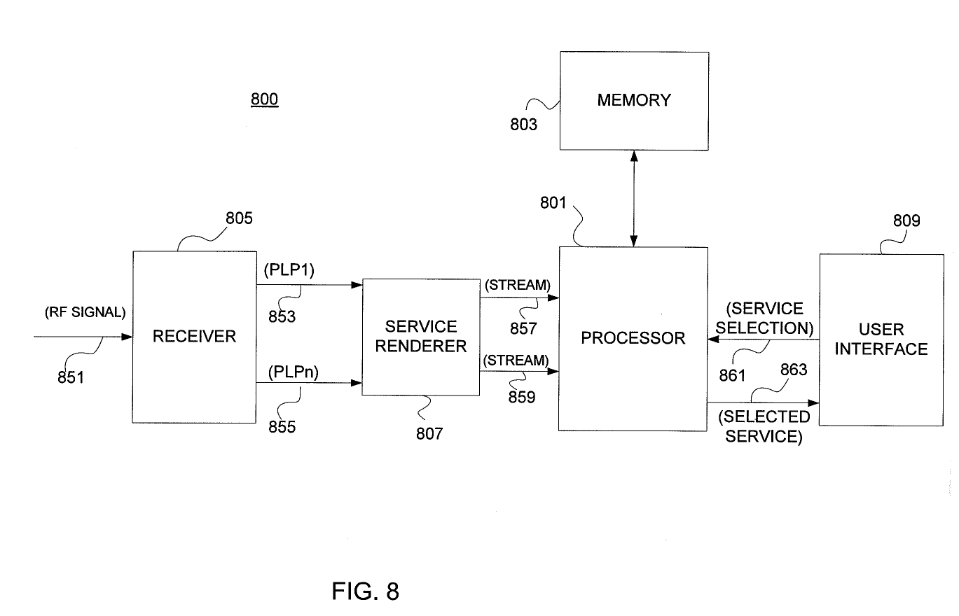

FIG. 8 shows apparatus 800 for processing a digital stream in accordance with some embodiments of the invention. Receiver 805 processes RF signal 851, e.g., a digital terrestrial television broadcast signal, to obtain PLPs 853 and 855. Service renderer 807 forms streams 857 and 859 for selected services from PLPs 853 and 855 based on service selection 861. Service selection 861 is determined from a user (not shown) choosing a service through user interface 809 and processor 801. Processor 801 then consequently provides service data 863 to user interface 809.

A user (not shown) chooses a service through user interface 809 to generate service selection indication 861 to processor 801. Accordingly, processor 801 selects PLPs 857 and 859 that are associated with the selected service in order to render the service on device 807.

Processor 801 may execute computer executable instructions from a computer-readable medium, e.g., memory 803 as described above in connection with FIG. 7.

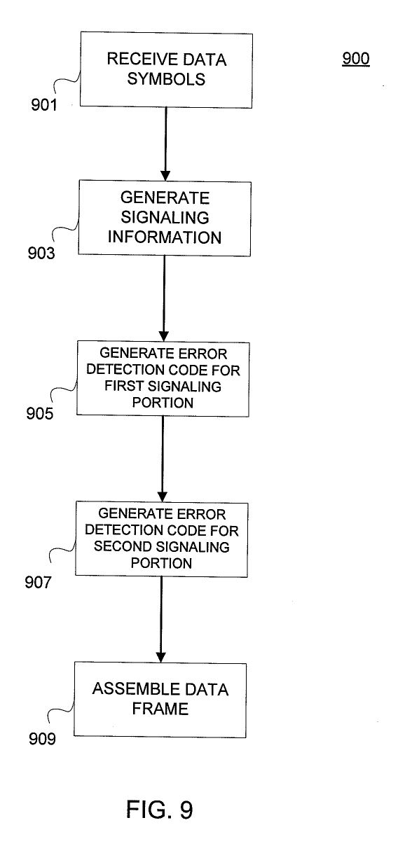

FIG. 9 shows flow diagram 900, which may be executed by processor 701 as shown in FIG. 7, for generating a data stream in accordance with an embodiment of the invention. In step 901, data symbols, which may represent content for a service, are received. In step 903, signaling data is generated for transmitting the data symbols through PLPs. In steps 905 and 907 error detection codes are generated for different portions of the signaling data, e.g., with separate CRCs. In step 909, a data frame is assembled with the encoded signaling portions and data symbols.

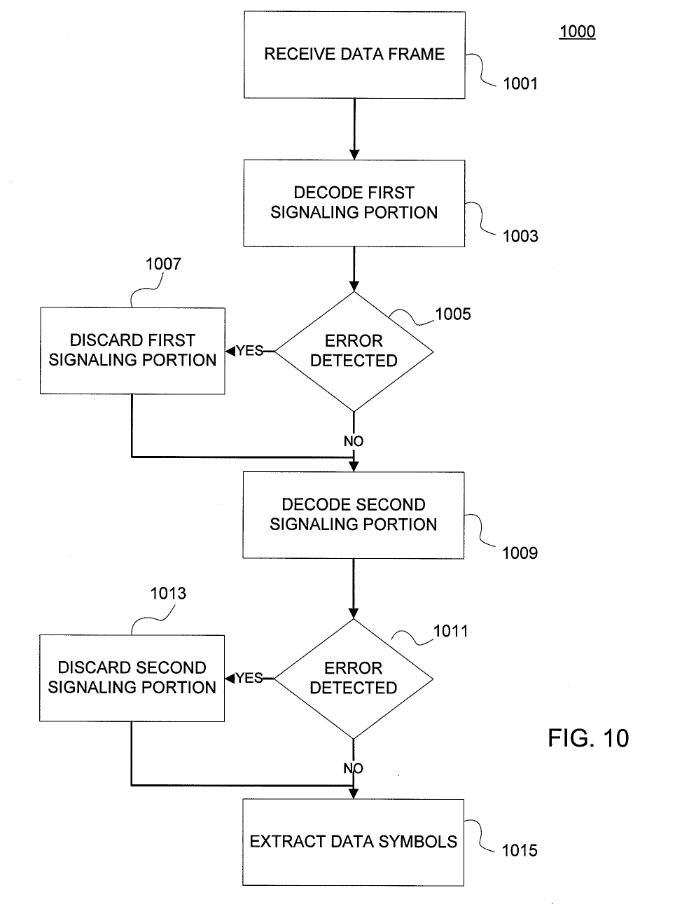

FIG. 10 shows flow diagram 1000, which may be executed by processor 801 as shown in FIG. 8, for processing a data stream in accordance with an embodiment of the invention. In step 1001, a data frame is received. A first signaling portion (e.g., L1-dyn N 405 as shown in FIG. 4) is decoded in step 1003. If an error is detected in step 1005, the first signaling portion is discarded. A second signaling portion (e.g., L1-dyn N+1 407) is decoded in step 1009. If an error is detected in the second signaling portion, it is discarded in step 1013. Consequently, even if an error occurs in one signaling portion, it is possible that the data frame may be usable, where the data symbols are extracted from the data frame in step 1015. For example, if the receiver is only interested in dynamic information as it receives a specific PLP, it could use L1 dynamic information even in case the signaling data includes some errors if it could be sure that the error occurs in other parts of the L1 post-signaling. When signaling data includes dynamic information for both the current and next frame PLP to frame mapping, the receiver could continue receiving data from the current frame if the error is known to occur in the part of signaling pertaining to the next frame.

While the invention has been described with respect to specific examples including presently preferred modes of carrying out the invention, those skilled in the art will appreciate that there are numerous variations and permutations of the above described systems and techniques that fall within the spirit and scope of the invention as set forth in the appended claims.

We claim:

1. A method comprising:
receiving data symbols for transmission in a data frame;
generating signaling information that identifies transmission parameters for the data frame, wherein the signaling information includes a first signaling portion and a second signaling portion;
generating a first error detection code for the first signaling portion;
generating a second error detection code for the second signaling portion; and
assembling the data frame comprising the first signaling portion, the first error detection code, the second signaling portion, the second error detection code, and the data symbols.

2. The method of claim 1, further comprising:
transmitting the data frame through a digital broadcasting system, wherein the signaling information comprises physical layer signaling data.

3. The method of claim 2, wherein the first signaling portion comprises a static part and the second signaling portion comprises a dynamic part.

4. The method of claim 2, wherein the first signaling portion comprises a first dynamic part and the second signaling portion comprises a second dynamic part.

5. The method of claim 1, further comprising:
using different modulation schemes to modulate the first signaling portion and the second signaling portion.

6. The method of claim 1, further comprising:
separately encoding the first signaling portion and the second signaling portion.

7. The method of claim 1, further comprising:
dividing the first signaling portion into a plurality of code words.

8. The method of claim 7, further comprising:
evenly distributing the plurality of code words over a transmission period.

9. An apparatus comprising:
a memory; and
a processor configured to retrieve computer-executable instructions from the memory and to perform:
receiving data symbols for transmission in a data frame;
generating signaling information that identifies transmission parameters for the data frame, wherein the signaling information includes a first signaling portion and a second signaling portion;
generating a first error detection code for the first signaling portion;
generating a second error detection code for the second signaling portion; and
assembling the data frame comprising the first signaling portion, the first error detection code, the second signaling portion, the second error detection code, and the data symbols.

10. The apparatus of claim 9, further comprising:
a transmitter configured to transmit the data frame through a digital broadcasting system, wherein the signaling information comprises physical layer signaling data.

11. The apparatus of claim 10, wherein the first signaling portion comprises a static part and the second signaling portion comprises a dynamic part.

12. The apparatus of claim 10, wherein the first signaling portion comprises a first dynamic part and the second signaling portion comprises a second dynamic part.

13. The apparatus of claim 9, wherein the processor is further configured to:
use different modulation schemes to modulate the first signaling portion and the second signaling portion.

14. The apparatus of claim 9, wherein the processor is further configured to:
separately encode the first signaling portion and the second signaling portion.

15. The apparatus of claim 9, wherein the processor is further configured to:
divide the first signaling portion into a plurality of code words.

16. The apparatus of claim 15, wherein the processor is further configured to:
evenly distribute the plurality of code words over a transmission period.

17. A computer-readable medium having computer-executable instructions that when executed perform:
receiving data symbols for transmission in a data frame;
generating signaling information that identifies transmission parameters for the data frame, wherein the signaling information includes a first signaling portion and a second signaling portion;
generating a first error detection code for the first signaling portion;
generating a second error detection code for the second signaling portion; and
assembling the data frame comprising the first signaling portion, the first error detection code, the second signaling portion, the second error detection code, and the data symbols.

18. The computer-readable medium of claim 17, wherein the instructions further perform:
transmitting the data frame through a digital broadcasting system, wherein the signaling information comprises physical layer signaling data.

19. The computer-readable medium of claim 18, wherein the first signaling portion comprises a static part and the second signaling portion comprises a dynamic part.

20. The computer-readable medium of claim 18, wherein the first signaling portion comprises a first dynamic part and the second signaling portion comprises a second dynamic part.

21. The computer-readable medium of claim 17, wherein the instructions further perform:
using different modulation schemes to modulate the first signaling portion and the second signaling portion.

22. The computer-readable medium of claim 17, wherein the instructions further perform:
separately encoding the first signaling portion and the second signaling portion.

23. The computer-readable medium of claim 17, wherein the instructions further perform:
dividing the first signaling portion into a plurality of code words.

24. The computer-readable medium of claim 23, wherein the instructions further perform:
evenly distributing the plurality of code words over a transmission period.

25. A method comprising:
receiving a data frame, wherein the data frame contains signaling information that identifies transmission parameters for the data frame and wherein the signaling information includes a first signaling portion and a second signaling portion;
determining whether a first error has occurred for the first signaling portion from a first error detecting code and whether a second error has occurred for the second signaling portion from a second error detecting code;
when the first error has occurred, discarding the first portion of the signaling data and when the second error has occurred, discarding the second portion of the signaling data; and
extracting data symbols from the data frame.

26. The method of claim 25, further comprising:
receiving the data frame through a digital broadcasting system, wherein the signaling information comprises physical layer signaling data.

27. The method of claim 26, wherein the first signaling portion comprises a static part and the second signaling portion comprises a dynamic part.

28. The method of claim 26, wherein the first signaling portion comprises a first dynamic part and the second signaling portion comprises a second dynamic part.

29. The method of claim 25, further comprising:
separately demodulating the first signaling portion and the second signaling portion.

30. The method of claim 25, further comprising:
separately decoding the first signaling portion and the second signaling portion.

31. The method of claim 25, further comprising:
obtaining the first signaling portion from a plurality of code words.

32. An apparatus comprising:
a memory; and
a processor configured to retrieve computer-executable instructions from the memory and to perform:
receiving a data frame, wherein the data frame contains signaling information that identifies transmission parameters for the data frame and wherein the signaling information includes a first signaling portion and a second signaling portion;
determining whether a first error has occurred for the first signaling portion from a first error detecting code and whether a second error has occurred for the second signaling portion of from a second error detecting code;
when the first error has occurred, discarding the first portion of the signaling data and when the second error has occurred, discarding the second portion of the signaling data; and
extracting data symbols from the data frame.

33. The apparatus of claim 32, further comprising:
a communications interface configured to receive the data frame through a digital broadcasting system, wherein the signaling information comprises physical layer signaling data.

34. The apparatus of claim 33, wherein the first signaling portion comprises a static part and the second signaling portion comprises a dynamic part.

35. The apparatus of claim 33, wherein the first signaling portion comprises a first dynamic part and the second signaling portion comprises a second dynamic part.

36. The apparatus of claim 32, wherein the processor is further configured to:
separately demodulate the first signaling portion and the second signaling portion.

37. The apparatus of claim 32, wherein the processor is further configured to:
separately decode the first signaling portion and the second signaling portion.

38. The apparatus of claim 32, wherein the processor is further configured to:
obtain the first signaling portion from a plurality of code words.

39. A computer-readable medium having computer-executable instructions that when executed perform:
receiving a data frame, wherein the data frame contains signaling information that identifies transmission parameters for the data frame and wherein the signaling information includes a first signaling portion and a second signaling portion;
determining whether a first error has occurred for the first signaling portion from a first error detecting code and whether a second error has occurred for the second signaling portion from a second error detecting code;
when the first error has occurred, discarding the first portion of the signaling data and when the second error has occurred, discarding the second portion of the signaling data; and
extracting data symbols from the data frame.

40. The computer-readable medium of claim 39, wherein the instructions further perform:
receiving the data frame through a digital broadcasting system, wherein the signaling information comprises physical layer signaling data.

41. The computer-readable medium of claim 40, wherein the first signaling portion of the comprises a static part and the second signaling portion comprises a dynamic part.

42. The computer-readable medium of claim 40, wherein the first signaling portion comprises a first dynamic part and the second signaling portion comprises a second dynamic part.

43. The computer-readable medium of claim 39, wherein the instructions further perform:
separately demodulating the first signaling portion and the second signaling portion.

44. The computer-readable medium of claim 39, further comprising:
separately decoding the first signaling portion and the second signaling portion.

45. The computer-readable medium of claim 39, further comprising:
obtaining the first signaling portion from a plurality of code words.
